(19) United States
(12) Patent Application Publication
(10) Pub. No.: US 2026/0213065 A1
(43) Pub. Date: Jul. 23, 2026

(54) COIL COMPONENT AND POWER SUPPLY DEVICE

(71) Applicant: TDK Corporation, Tokyo (JP)

(72) Inventors: Akira Hiraoka, Tokyo (JP); Daiki Hiraoka, Tokyo (JP); Takuya Sakamoto, Tokyo (JP)

(73) Assignee: TDK Corporation, Tokyo (JP)

(21) Appl. No.: 19/451,105

(22) Filed: Jan. 16, 2026

(30) Foreign Application Priority Data
Jan. 23, 2025 (JP) 2025-009961

(51) Int. Cl. H01F 27/32; H01F 27/24; H05K 1/181; H05K 7/14

(52) U.S. Cl. CPC H01F 27/325; H01F 27/24; H05K 1/181; H05K 7/1427; H05K 2201/1003

(57) ABSTRACT

Provided is a technology relating to a coil component that can minimize the number of components while incorporating additional functions into a bobbin. A coil component includes a core, a coil member that is provided relative to the core, a bobbin that houses the coil member and includes first and second bobbin members. The first bobbin member includes a first flange that is located on one side of an axial direction of the coil member to insulate the coil member from the core, and the second bobbin member includes a second flange that is located on another side of the axial direction of the coil member to insulate the coil member from the core. The second flange is formed from a printed circuit board.

### CROSS REFERENCE TO RELATED APPLICATIONS

This application claims the benefit of Japanese Priority Patent Application No. 2025-009961 filed on Jan. 23, 2025, the entire contents of which are incorporated herein by reference.

### FIELD

The present disclosure relates to a coil component and a power supply device including the coil component.

### BACKGROUND

A coil component that includes a coil winding and a bobbin for coil is used in a transformer of a power supply device or the like to be incorporated in a charger for a vehicle battery, or the like. The bobbin for coil is used for the purpose of positioning the coil winding and also preventing the coil windings from shorting out with each other or with other components.

For example, Patent Publication JP-A-2019-012715 discloses a bobbin that can be disassembled into a first bobbin member and a second bobbin member. The first bobbin member has a bottom plate with a first opening formed in the center thereof, a cylindrical body standing on the bottom plate so as to communicate with the first opening, and the like. The second bobbin member has a plate-shaped first insulator having a second opening formed in the center thereof, and a plate-shaped second insulator having a third opening formed in the center thereof. When the cylindrical body of the first bobbin member is inserted into a spirally formed first coil member, and the cylindrical body is inserted into the second and third openings of the second bobbin member with the second coil member sandwiched between the first insulator and the second insulator of the second bobbin member, each coil member is positioned and insulated.

### SUMMARY

However, when a current passes through the coil component, high-frequency noise is generated. Adding a smoothing condenser or capacitor to provide the function of reducing high-frequency noise increases the number of components. Other approaches to provide other functions also increases the number of components. An increase in the number of components in a power supply device leads to an increase in the size of the housing and an increase in the manufacturing costs.

The present disclosure has been made in consideration of the above circumstances, and aims to provide a technology relating to a coil component that can minimize the number of components while incorporating additional functions into a bobbin.

A coil component according to one aspect of the present disclosure includes: a core; a coil member that is provided relative to the core; and a bobbin that houses the coil member and includes first and second bobbin members, wherein the first bobbin member includes a first flange that is located on one side of an axial direction of the coil member to insulate the coil member from the core, the second bobbin member includes a second flange that is located on another side of the axial direction of the coil member to insulate the coil member from the core, and the second flange is formed from a printed circuit board.

According to this aspect, since a portion of the bobbin is configured as a printed circuit board, there is no need to prepare a separate board for mounting electronic components. The printed circuit board allows various electronic components to be mounted thereon, and therefore, the number of components can be minimized while incorporating additional functions into the bobbin according to the electronic components to be mounted. The printed circuit board may be a bare-board printed wiring board (PWB) with no electronic components mounted thereon, or a printed circuit board (PCB) with electronic components mounted thereon and operating as an electronic circuit. Such a printed circuit board is also highly productive because it can be manufactured using punching, routing, or the like, without the need for molds.

In the above aspect, an electronic component may be mounted on the printed circuit board.

According to this aspect, the function of the electronic component mounted on the printed circuit board can be added to the bobbin.

In the above aspect, the electronic component may include a capacitor and/or a condenser.

According to this aspect, by the capacitor and/or condenser, a function of reducing high frequency noise can be added to the bobbin.

In the above aspect, the printed circuit board may be formed from a high heat dissipation board.

According to this aspect, a heat dissipation function that efficiently dissipates heat generated from the electronic component to the printed circuit board can be added to the bobbin. The high heat dissipation board may be aluminum-based or copper-based.

In the above aspect, the printed circuit board may be provided with a positioning portion that restricts movement of the core.

According to this aspect, a function of positioning the core can be added to the bobbin.

In the above aspect, the electronic component mounted on the printed circuit board may overlap with the coil member in plan view.

According to this aspect, the electronic component does not protrude from the space of the coil member in plan view, so that the printed circuit board can be made compact.

In the above aspect, a power supply device may include the coil component.

Each coil component according to the above aspects is suitable for a power supply device, a new function is added as an additional function of the coil component, and therefore, the number of components in the power supply device can be minimized, preventing the size of the housing from increasing and the manufacturing costs from increasing.

In the above aspect, the power supply device may include a housing, a main board, and a fastening portion that fastens the housing and the main board together, and the fastening portion may include a GND terminal, and the housing and the GND terminal may be electrically connected to each other.

According to this aspect, since the GND terminal of the printed circuit board is connected to the housing having the lowest potential, the performance of removing noise components from outputs can be improved via a capacitor and/or condenser. For the above reasons, the housing is less susceptible to the effects of conductive noise from external electromagnetic waves from outside of the housing.

In the above aspect, the power supply device may further include a bus bar that functions as an output terminal of the power supply device, and the bus bar may be fixed to the printed circuit board.

According to this aspect, the bus bar, which is less likely to deform and easier to be positioned than a cable, is routed and fixed to the printed circuit board, allowing the power supply device to be configured compactly.

According to the present disclosure, it is possible to provide a technology relating to a coil component that can minimize the number of components while incorporating additional functions into a bobbin.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view illustrating an example of a power supply device including a coil component according to one aspect of the present disclosure;

FIG. 2 is a circuit diagram illustrating the power supply device illustrated in FIG. 1;

FIG. 3 is a plan view illustrating an output terminal side illustrated in FIG. 1;

FIG. 4 is a cross-sectional view taken along line IV-IV illustrated in FIG. 3;

FIG. 5 is a perspective view of a coil component illustrated in FIG. 3;

FIG. 6 is an exploded perspective view of the coil component illustrated in FIG. 5;

FIG. 7 is a plan view illustrating a second flange illustrated in FIG. 6; and

FIG. 8 is an exploded perspective view illustrating a modified example of the coil component according to one aspect of the present disclosure.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

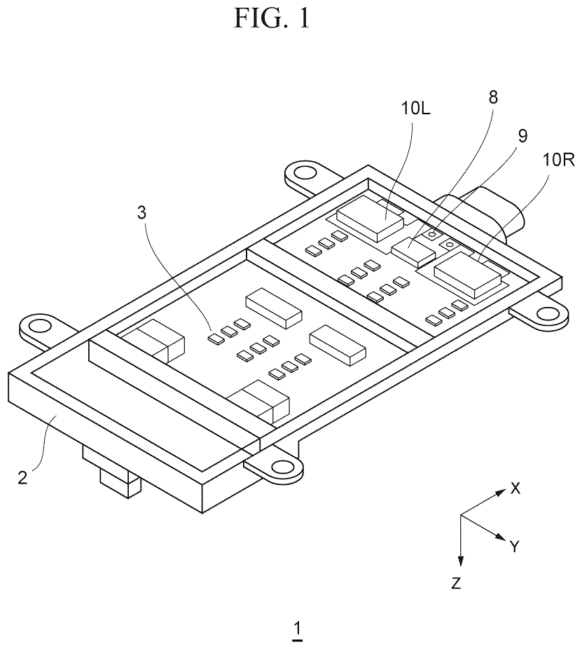

An example embodiment of the present disclosure will be described with reference to the accompanying drawings. Note that elements designated by same reference signs in the respective drawings share an identical or a similar configuration. With reference to FIGS. 1 to 8, details of their respective configurations will be described below.

FIG. 1 is a perspective view illustrating an example of a power supply device 1 including a coil component 10 according to one aspect of the present disclosure. As in the illustrated example, the coil component 10 according to the present disclosure is suitable for the power supply device 1. The power supply device 1 may include a housing 2 and a main board 3 in addition to the coil component 10. A new function is added as an additional function of the coil component 10, and therefore, the number of components in the power supply device 1 can be minimized, preventing the size of the housing 2 from increasing and the manufacturing costs from increasing. However, the application of the coil component 10 is not limited to the power supply device 1, but the coil component 10 can be applied to various devices.

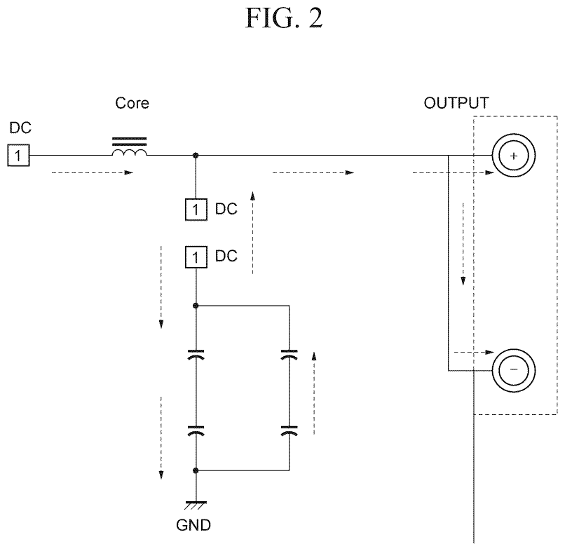

FIG. 2 is a circuit diagram illustrating the power supply device 1 illustrated in FIG. 1. As in the illustrated example, the power supply device 1 functions as a DC-DC converter, and converts a high-voltage DC input voltage supplied from a high-voltage battery or the like that stores, for example, a voltage of about 100 V to 500 V into a low-voltage DC output voltage, which is in turn supplied from an output terminal (OUTPUT) to a low-voltage battery or the like that stores a voltage of about 12 to 16 V.

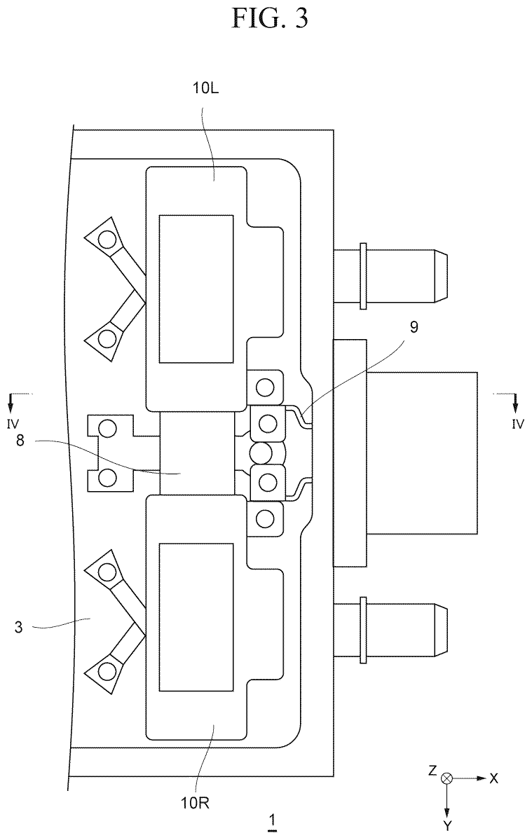

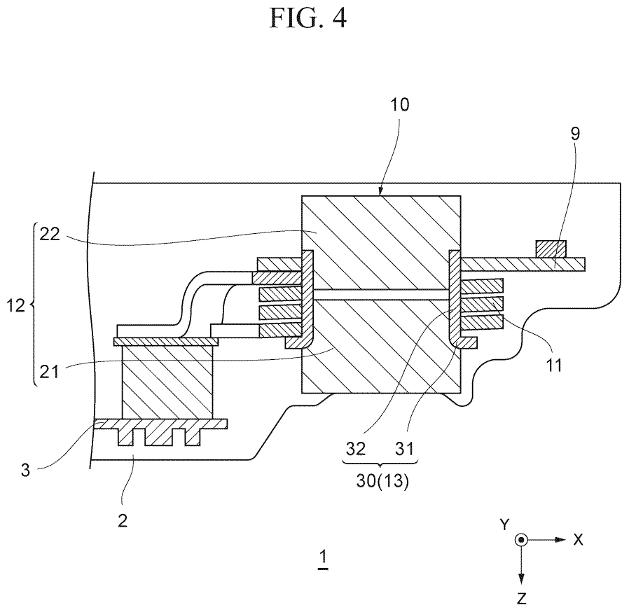

FIG. 3 is a plan view illustrating an output terminal side illustrated in FIG. 1. FIG. 4 is a cross-sectional view taken along line IV-IV illustrated in FIG. 3. As in the illustrated example, the power supply device 1 may drop the voltage before supplying power to other components. As in the illustrated example, a pair of left and right coil components 10L and 10R may be provided. The current that has passed through one coil component 10L passes through a central magnet 8, reducing noise, and then passes through the other coil component 10R and then through the central magnet 8 again, reducing noise.

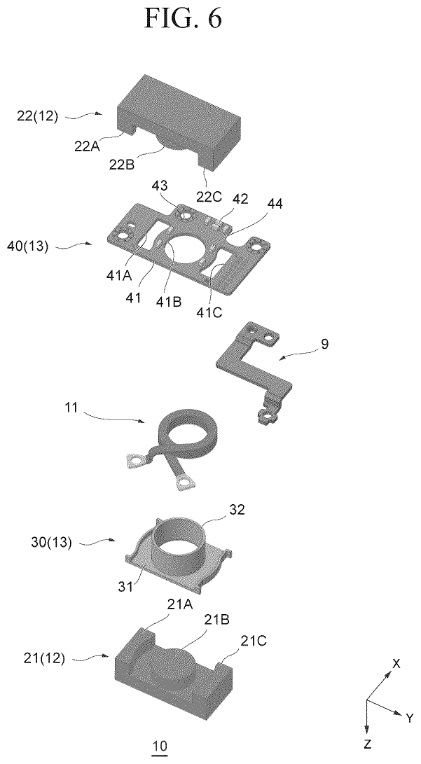

As in the illustrated example, the power supply device 1 may include a bus bar 9 that functions as an output terminal of the power supply device 1. The bus bar 9 is fixed to a second flange 41 (illustrated in FIG. 6) that is a printed circuit board. According to the illustrated example, the bus bar 9, which is less likely to deform and easier to be positioned than a cable, is routed and fixed to the printed circuit board, allowing the power supply device 1 to be configured compactly.

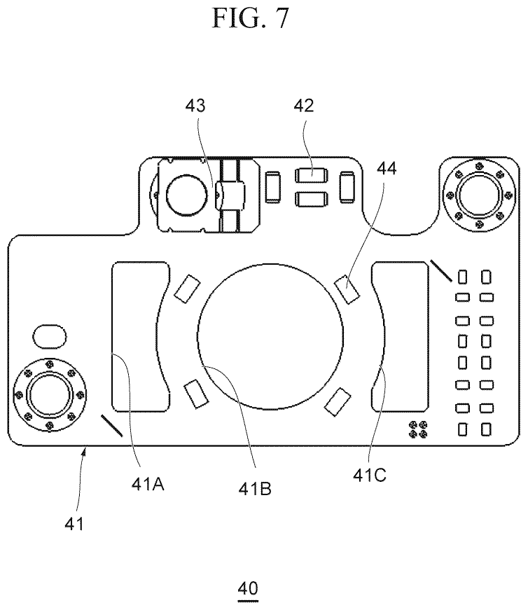

In the plan view illustrated in FIG. 3, at least one of the electronic components mounted on the printed circuit board (e.g., an electronic component 44 illustrated in FIG. 7) may overlap with the coil component 10. According to the illustrated example, the second flange 41, which is a printed circuit board where electronic components can be integrated, can be configured compactly.

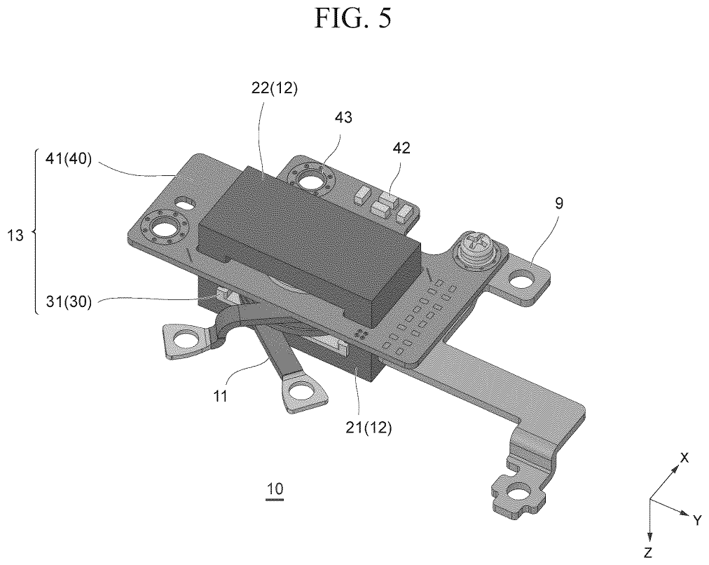

FIG. 5 is a perspective view of the coil component 10 illustrated in FIG. 3. FIG. 6 is an exploded perspective view of the coil component 10 illustrated in FIG. 5. As illustrated, the coil component 10 according to one aspect of the present disclosure includes a bobbin 13 that can be separated into a first bobbin member 30 and a second bobbin member 40, a coil member 11 that is spirally wound around a winding core 32 of the bobbin 13, and a core 12 that surrounds the coil member 11.

As illustrated, the core 12 may be configured to be separable into a first core member 21 and a second core member 22. In the illustrated example, the core 12 is an EE core, and both the first and second core members 21 and 22 are formed in an E shape. The first core member 21 has first and third protrusions 21A and 21C each having a concave cylindrical surfaces that conform to the outer periphery of the coil member 11, and a cylindrical second protrusion 21B interposed between the first and third protrusions 21A and 21C.

The second protrusion 21B is inserted into the winding core 32 of the bobbin 13 and is disposed at the center of the coil member 11. The shapes of the first to third protrusions 21A to 21C are not limited to the illustrated examples. When the coil member 11 is wound in a polygonal spiral shape instead of a circular spiral shape, each protrusion may be formed in a shape that conforms to that.

The second core member 22 has first to third protrusions 22A to 22C similar to those of the first core member 21. The first and second core members 21 and 22, which is an EE core, surround the coil member 11 in a way that the first and third protrusions 21A, 21C and 22A, 22C face the outer peripheral surface of the coil member, and the second protrusions 21B and 22B face the inner peripheral surface of the coil member 11.

The configuration of the core 12 is not limited to the illustrated example, and either one of the first and second core members 21 and 22 may be an I-type EI core. The core 12 is a magnetic material, and can be formed by compacting ferrite powder into an E-type or I-type.

The first bobbin member 30 includes, in addition to the cylindrical winding core 32, a first flange 31 that is located on one side in an axial direction of the coil member 11 (in the illustrated example, on the bottom side in a depth direction Z of the housing 2) to insulate the coil member 11 from the first core member 21 of the core 12. The first flange 31 is formed in a plate shape with a through-hole 31B formed therein. On an outer edge of the first flange 31, a protrusion may be provided to prevent the first core member 21 from rotating on its axis.

The through-hole 31B opens to communicate with the internal space of the cylindrical winding core 32. The winding core 32 and the first flange 31 may be formed from a resin material as an integral structure, or the winding core 32 and the first flange 31 may be separable assemblies each formed from a resin material.

The second bobbin member 40 includes a second flange 41 that is located on the other side in the axial direction of the coil member 11 (in the illustrated example, on the lid side in the depth direction Z of the housing 2) to insulate the coil member 11 from the second core member 22 of the core 12. The second flange 41 is formed in a plate shape with through-holes 41A to 41C formed therein.

The through-hole 41B is open to communicate with the internal space of the cylindrical winding core 32. The first and third protrusions 22A and 22C of the second core member 22 are inserted into the through-holes 41A and 41B, respectively. The through-holes 41A and 41B are an example of a positioning portion that restricts movement of the core 12 relative to the second bobbin member 40 (e.g., prevents the second core member 22 from rotating on its axis, etc.).

FIG. 7 is a plan view illustrating the second flange 41 illustrated in FIG. 6. the second flange 41 is formed from a printed circuit board on which electronic components can be mounted. The printed circuit board, which constitutes the second flange 41, may be a bare-board printed wiring board (PWB) with no electronic components mounted thereon, or a printed circuit board (PCB) with electronic components mounted thereon and operating as an electronic circuit. Such a printed circuit board is also highly productive because it can be manufactured using punching, routing, or the like, without the need for molds.

As in the illustrated example, the printed circuit board, which constitutes the second flange 41, may be formed from a high heat dissipation board. By the second flange 41 being formed from a high heat dissipation board, a heat dissipation function that efficiently dissipates heat generated from the electronic components to the second flange 41 can be added to the bobbin 13. The high heat dissipation board may be aluminum-based or copper-based.

As in the illustrated example, at least one of the electronic components may include a capacitor and/or a condenser. In the illustrated example, the electronic component 42 is a capacitor or a condenser, and by the electronic component 42, a function of reducing high frequency noise can be added to the bobbin 13.

As in the illustrated example, at least one of the electronic components may be a GND terminal. In the illustrated example, the electronic component 43 is a GND terminal, and when the electronic component 43 is electrically connected to the housing 2 illustrated in FIG. 1, the printed circuit board of the second flange 41 is connected to the housing 2 with the lowest potential, thereby stabilizing the potential of the coil component 10. The coil component 10 is less susceptible to the effects of external electromagnetic waves from the main board 3 and the like.

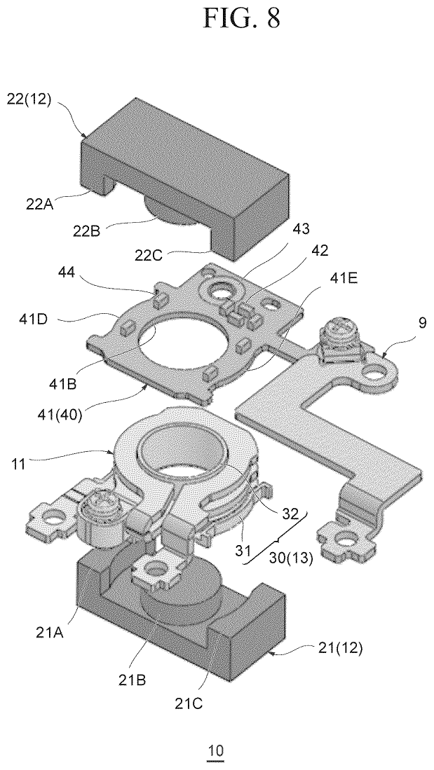

FIG. 8 is an exploded perspective view illustrating a modified example of the coil component 10 according to one aspect of the present disclosure. As in the modified example, instead of through-holes in the printed circuit board, outer edges 41D and 41E of the printed circuit board may be configured as positioning portions that restrict movement of the core 12. The coil member 11 may be configured to be separable into a plurality of coil members. In the illustrated example, the coil member 11 is configured as an assembly of two coil members stacked in the axial direction.

According to one aspect and its modified example of the present disclosure configured as described above, since a portion of the bobbin is configured as a printed circuit board, there is no need to prepare a separate board for mounting electronic components. The printed circuit board allows various electronic components to be mounted thereon, and therefore, the number of components can be minimized while incorporating additional functions into the bobbin according to the electronic components to be mounted.

The above-described example embodiments are intended to facilitate understanding of the present disclosure and are not intended to limit the present disclosure. The elements of the example embodiments, as well as their arrangement, materials, conditions, shapes, sizes, etc., are not limited to those exemplified and can be modified as appropriate. Furthermore, configurations present in different example embodiments can be partially substituted or combined with each other.

1. A coil component comprising:
a core;
a coil member that is provided relative to the core; and
a bobbin that houses the coil member and includes first and second bobbin members, wherein
the first bobbin member includes a first flange that is located on one side of an axial direction of the coil member to insulate the coil member from the core,
the second bobbin member includes a second flange that is located on another side of the axial direction of the coil member to insulate the coil member from the core, and
the second flange is formed from a printed circuit board.

2. The coil component according to claim 1, wherein an electronic component is mounted on the printed circuit board.

3. The coil component according to claim 2, wherein the electronic component includes a capacitor and/or a condenser.

4. The coil component according to claim 2, wherein the printed circuit board is formed from a high heat dissipation board.

5. The coil component according to claim 2, wherein the printed circuit board is provided with a positioning portion that restricts movement of the core.

6. The coil component according to claim 2, wherein the electronic component mounted on the printed circuit board overlaps with the coil member in plan view.

7. A power supply device comprising the coil component according to claim 1.

8. The power supply device according to claim 7, comprising: a housing; a main board; and a fastening portion that fastens the housing and the main board together, wherein
the fastening portion includes a GND terminal, and the housing and the GND terminal are electrically connected to each other.

9. The power supply device according to claim 7, further comprising a bus bar that functions as an output terminal of the power supply device, wherein the bus bar is fixed to the printed circuit board.

10. A power supply device comprising the coil component according to claim 2.

11. The power supply device according to claim 10, comprising: a housing; a main board; and a fastening portion that fastens the housing and the main board together, wherein
the fastening portion includes a GND terminal, and the housing and the GND terminal are electrically connected to each other.

12. The power supply device according to claim 10, further comprising a bus bar that functions as an output terminal of the power supply device, wherein the bus bar is fixed to the printed circuit board.

13. A power supply device comprising the coil component according to claim 3.

14. The power supply device according to claim 13, comprising: a housing; a main board; and a fastening portion that fastens the housing and the main board together, wherein
the fastening portion includes a GND terminal, and the housing and the GND terminal are electrically connected to each other.

15. The power supply device according to claim 13, further comprising a bus bar that functions as an output terminal of the power supply device, wherein the bus bar is fixed to the printed circuit board.

16. A power supply device comprising the coil component according to claim 4.

17. The power supply device according to claim 16, comprising: a housing; a main board; and a fastening portion that fastens the housing and the main board together, wherein
the fastening portion includes a GND terminal, and the housing and the GND terminal are electrically connected to each other.

18. The power supply device according to claim 16, further comprising a bus bar that functions as an output terminal of the power supply device, wherein the bus bar is fixed to the printed circuit board.

19. A power supply device comprising the coil component according to claim 5.

20. A power supply device comprising the coil component according to claim 6.
